(19) United States
(12) Patent Application Publication
(10) Pub. No.: US 2008/0032161 A1
(43) Pub. Date: Feb. 7, 2008

(54) Coated Product And Method Of Production Thereof

(76) Inventors: Mikael Schuisky, Sandviken (SE); Jens Petter Palmquist, Uppsala (SE)

Correspondence Address: DRINKER BIDDLE & REATH (DC), 1500 K STREET, N.W., SUITE 1100, WASHINGTON, DC, 20005-1209, US

(21) Appl. No.: 11/664,589

(22) PCT Filed: Nov. 4, 2005
(86) PCT No.: PCT/SE05/01667

§ 371 Date: Sep. 26, 2007

(30) Foreign Application Priority Data
Nov. 4, 2004 (SE) 0402701-7
Nov. 22, 2004 (SE) 0402865-0

(51) Int. Cl. H01M 8/00; C23C 14/06; C23C 14/14; H01R 3/00; H01B 1/02

(52) U.S. Cl. 429/12; 106/1.22; 428/220; 428/621

(57) ABSTRACT

A new coated product is disclosed consisting of a metallic substrate and a coating of a MAX material type. Furthermore, a method of producing such a coated product is disclosed using vapor deposition technique in a continuous roll to roll process.

The present disclosure relates to a coated product, such as a coated strip, which consists of a metallic substrate and a coating of a so called MAX material. Furthermore, the present disclosure relates to the manufacturing of such a coated product.

### BACKGROUND AND PRIOR ART

A MAX material is a ternary compound with the following formula Mₙ₊₁A_{z}Xₙ. M is at least one transition metal selected from the group of Ti, Sc, V, Cr, Zr, Nb, Ta; A is at least one element selected from the group consisting of Si, Al, Ge and/or Sn; and X is at least one of the non-metals C and/or N. The ranges of the different components of the single phase material is determined by n and z, wherein n is within the range of 0.8-3.2 and z is within the range of 0.8-1.2. Consequently, examples of compositions within the MAX material group are Ti₃SiC₂, Ti₂AlC, Ti₂AlN and Ti₂₅ nC.

MAX materials may be used in several different environments. These materials have among other properties a good electrical conductivity, are high temperature resistant, have high corrosion resistance as well as low friction and are relatively ductile. Some MAX materials are also known to be bio-compatible. Consequently, MAX materials and coatings of MAX materials on metallic substrates are well suited for use as for example electrical contact materials in corrosive environments and at high temperatures, wear resistant contact materials, low friction surfaces in sliding contacts, interconnects in fuel cells, coatings on implants, decorative coatings and non-sticking surfaces, just to name a few.

It is previously known to accomplish articles coated with MAX materials in batch processes, see for example WO 03/046247 A1. Furthermore, WO2005/038985 A2 discloses an electrical contact element having a coating of MAX material whereby the coating is produced by PVD or CVD in a batch process. However, such processes do not produce a cost effective material and uses fairly advanced technology by for example utilising a seed layer as in WO 03/046247 A1. Therefore, there is a need of a process to produce a cost effective substrate material with a dense coating of MAX material.

Consequently, it is an object of the present invention to manufacture a substrate coated with a MAX material in a cost effective manner while at the same time accomplish a dense MAX material coating with a good adhesion to the substrate.

### SUMMARY

The object is achieved by a method of coating of a metal substrate with a coating having a composition of Mₙ₊₁A_{z}Xₙ, wherein M is at least one metal selected from the group of Ti, Sc, V, Cr, Zr, Nb, Ta; A is at least one element selected from the group consisting of Si, Al, Ge and/or Sn; and X is at least one of the non-metals C and/or N, n is within the range of 0.8-3.2 and z is within the range of 0.8-1.2, is coated onto the surface of the substrate continuously by usage of vapour phase deposition technique. This enables large scale objects consisting of a substrate and a coating to be produced in a cost effective manner and with the desired properties throughout the whole product. The MAX coated metal substrate is advantageously used in production of electrical contact materials, more specifically components to be used in electrical devices.

### BRIEF DESCRIPTION OF THE DRAWINGS

FIG. 1 illustrates the result of a GDOES analysis of a MAX coated metal substrate in accordance with one embodiment of the present invention.

FIG. 2 illustrates the result of a GDOES analysis of a MAX coated metal substrate in accordance with another embodiment of the present invention.

### DETAILED DESCRIPTION

A substrate coated with MAX material is produced in a continuous roll-to-roll process whereby, among other properties, a good adhesion of the coating over the total surface of the substrate is accomplished. In this context a good adhesion is considered to mean that the product is able to be bent at least 90 degrees over a radius equal to the thickness of the substrate without showing any tendency to flaking, spalling or the like, of the coating.

The composition of the substrate material could be any metallic material. Typically, substrate material is selected from the group consisting of Fe, Cu, Al, Ti, Ni, Co and alloys based on any of these elements, but other substrate materials, such as those typically selected for the application can be used. Some examples of suitable materials to be used as substrates are ferritic chromium steels of the Type AISI 400-series, austenitic stainless steels of the type AISI 300-series, hardenable chromium steels, duplex stainless steels, precipitation hardenable steels, cobalt alloyed steels, Ni based alloys or alloys with a high content of Ni, and Cu based alloys. According to a preferred embodiment, the substrate is a stainless steel with a chromium content of at least 10% by weight.

The substrate may be in any condition, such as soft annealed, cold-rolled or hardened condition as long as the substrate is able to withstand the coiling on the rolls of the production line.

The substrate is a metallic substrate material in the form of a strip, foil, wire, fibre, tube or the like. According to a preferred embodiment the substrate is a in the form of a strip or foil.

The length of the substrate is at least 10 meters in order to ensure a cost effective coated product. Preferably, the length is at least 50 meters and most preferably at least 100 meters. In fact, the length might be up to at least 20 km, and for certain product forms such as fibres, it might be even much longer.

The thickness of the substrate when in the form of a strip or foil is usually at least 0.015 mm thick, preferably at least 0.03 mm, and up to 3.0 mm thick, preferably maximally 2 mm. The most preferred thickness is within the range of 0.03-1 mm. The width of the strip is usually between 1 mm and 1500 mm. However, according to a preferred embodiment the width is at least 5 mm, but at the most 1 m.

The composition of the MAX material coating is Mₙ₊₁A_{z}Xₙ. M is at least one transition metal selected from the group of Ti, Sc, V, Cr, Zr, Nb, Ta; A is at least one element selected from the group consisting of Si, Al, Ge and/or Sn; and X is at least one of the non-metals C and/or N. The ranges of the different components of the single phase material is determined by n and z, wherein n is within the range of 0.8-3.2 and z is within the range of 0.8-1.2.

The crystallinity of the coating may vary from amorphous or nanocrystalline to well crystallised and near single phase material. Naturally, this can be accomplished by control of temperature or other process parameters during growth of the coating, i.e. during deposition. For example, a higher temperature during deposition of the coating may render a coating of a higher crystallinity. According to different embodiments, the crystallinity may be substantially single phased, amorphous and/or crystalline. By substantially is meant that other forms of crystallinity is merely present in amounts not effecting the properties of the coating.

The coating has a thickness adapted to the usage of the coated product. However, it is preferred that the thickness of the coating is at least 5 nm, preferably at least 10 nm; and not more than 25 μm, preferably not more than 10 μm, most preferably not more than 5 μm. Suitable thicknesses usually falls within the range of 50 nm-2 μm.

The substrate may be provided with the coating by any method resulting in a dense and adherent coating. In one example the coating is performed using vapour phase deposition technique in a continuous roll to roll process. Vapour deposition technique includes CVD processes as well as PVD processes. Examples of applicable PVD processes are magnetron sputtering and electron beam evaporation. The electron beam evaporation process can be both plasma activated and/or reactive if needed, in order to form a dense and well adherent layer.

Naturally, the surface of the substrate has to be cleaned in a proper way before coating, for example to remove oil residues and/or the native oxide layer of the substrate.

An advantage of the use of PVD technique is that the substrate material is not heated as much as would be required during for example a CVD process. Consequently, the risk of deterioration of the substrate material during coating is reduced. Deterioration of the substrate may be further prevented with the aid of controlled cooling of the substrate during coating. Also, the risk of contamination of the MAX material during the coating procedure is substantially less compared to CVD which uses precursor and carrier gases containing elements which may unintentionally and undesirably be incorporated in the coating.

In a continuous process, the substrate speed during coating is at least 1 meters/minute; preferably the substrate speed is at least 3 meters/minute and most preferably at least 10 meters/minute. The high speed contributes to producing the product in a cost effective way. Furthermore, high speed also reduces the risk of deterioration of the substrate material whereby a higher quality of the product may be achieved.

In the case where the substrate is a strip or foil it may be provided with a coating on one side or on both sides. In the case the coating is provided on both surfaces of the strip, the composition of the coatings on each side of the strip may be the same but may also differ depending on the application in which the coated product will be used. The strip may be coated on both sides simultaneously or on one side at a time.

The coating may for example be produced by vaporising a target of a MAX material and depositing onto the substrate according to the definition stated above. The coating may be produced in several coating chambers located in line, but it may also be produced in one single chamber.

In some cases it might be applicable to provide an optional thin bonding layer between metal substrate and the coating in order to further improve the adhesion of the coating. The bonding layer may for example be based on one of the metals from the MAX material but also other metallic materials may be used as bonding layer. The bonding layer is preferably as thin as possible, not more than 50 nm, preferably not more than 10 nm. The bonding layer may be applied by any conventional method such as vapour deposition processes, electrochemical process etc.

In the case where the substrate is a strip or foil an alternative embodiment has one surface of the substrate coated with a MAX material while the other surface is coated with a different material, for example a non-conductive material or a material which will improve soldering, such as Sn or Ni. In these cases the MAX coating may be applied to one side of the substrate and for example an electrically isolating material such as Al₂O₃ or SiO₂ may be applied to the other side of the substrate. This may be done in-line with the coating of MAX material in separate chambers, or it may be done at separate occasions.

MAX materials are well known for their electrical conductivity and the coated product in accordance with the present disclosure is highly suitable for electrical contact materials. By utilising magnetron sputtering or electron beam evaporation it is possible to coat a substrate of steel with MAX material without deteriorating the properties of the substrate.

According to an embodiment, the coated product is advantageously used for production of spring elements to be used in various electronic devices as it combines the necessary features of excellent resistance to relaxation and fatigue and well controlled contact resistance, with excellent workability enabling substantial forming such as bending, stamping, cutting or the like without showing any tendencies of cracking, spalling or the like of the coating. For these applications the substrate should be a stainless steel with at least 10% Cr and with a strip thickness of 3 mm or less. The tensile strength of the substrate should be at least 1000 MPa, preferably at least 1500 MPa, which may be achieved for suitable materials by means of cold working or heat treatment, before or after coating with the MAX material. Examples of spring elements which could advantageously be produced from the MAX coated substrate are switches, connectors and metallic domes. Using these above mentioned PVD methods also enables the possibility of controlling the thickness of the coating within small tolerances thereby rendering a large scale product consisting of a substrate and a coating which product has substantially the same properties throughout the whole product. Furthermore, components such a metallic domes can be manufactured in a cost effective manner as they are formed, for example by means of stamping and/or upsetting, out such a large scale object.

According to an embodiment, the method and coated product according to the present disclosure is used for production of interconnects for fuel cells. In this case the substrate is preferably a ferritic stainless steel. In Solid Oxide Fuel Cells (SOFC) it is important to have a small difference in thermal expansion between the interconnect and the rest of the components as well as a low contact resistance which will not be increased over time due to the corrosive environment to which the interconnect is exposed. A MAX coated ferritic stainless steel fulfils the above criteria which make the present method and coated product highly suitable to be used for production of interconnects.

According to a further embodiment, the method and coated product can be used for production of components which will be in the vicinity or direct contact with body fluids, body tissue or skin, either human or animal. These components may for example be in the form of a tube, wire, foil or strip. Examples of such components are surgical knives, needles, catheters or the like. For this application the MAX material preferably contains Ti and the substrate is a stainless steel substrate which in itself is biocompatible. One example of a suitable substrate for this application is a stainless steel with an approximate composition of 0.3-0.4 wt-% of C, 0.2-0.5 wt-% of Si, 0.3-0.6 wt-% Mn, 12-14 wt-% Cr and optionally 0.5-1.5 wt-% of Mo.

### EXAMPLE 1

A substrate has been coated with a MAX material by magnetron sputtering from a target having the following composition: Ti₃SiC₂. The substrate was a metallic substrate material in the form of a strip of FeCrNi-alloy coated with a Ni-layer. The substrate had an approximate composition of 0.1 wt-% C, 1.2 wt-% Si, 1.3% Mn, 16.5 wt-% Cr and 7 wt-% Ni and is suitable for springs and other high strength components in the mechanical, electronics and computer industries. It is a very good spring material that fulfils the demands regarding corrosion resistance, mechanical strength, fatigue and relaxation properties commonly set for the above identified applications. For example, a tensile strength of up to approximately 1900 MPa can easily be accomplished by cold rolling, and even up to approximately 2000 MPa if cold rolled and tempered.

The substrate was cleaned by plasma etching prior to coating. The substrate temperature was controlled by the temperature of the coating chamber and held at 500° C. The substrate was moving in front of the target.

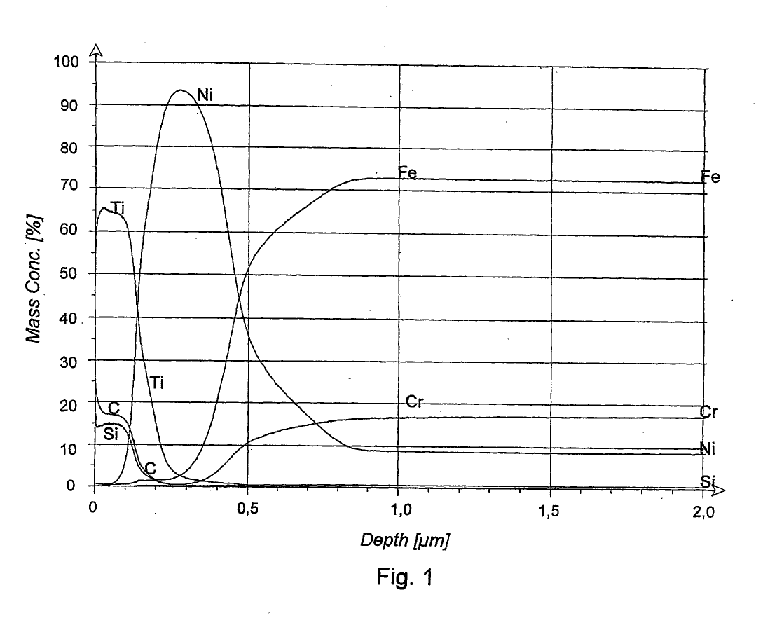

FIG. 1 shows a depth profile of the composition of the coating, as measured by GDOES (Glow Discharge Optical Emission Spectroscopy). As can be seen, the relative mass concentration in the film has been measured to Ti˜65%; Si˜15%; C˜17%, this corresponds to a atomic Ti:Si relationship close to 3:1. The carbon content is high (corresponding to Ti:C close to 1:1), however, high carbon contents in thin films are hard to determine with any accuracy due to contamination and calibration problems related to the measurement technique. Therefore it is likely to assume that the MAX film has an overall composition close to Ti:Si:C=3:1:2, as provided from the MAX target.

### EXAMPLE 2

A substrate has been coated with a very thin coating of MAX material by magnetron sputtering from a target having the following composition: Ti₃SiC₂. The substrate was a metallic substrate material in the form of a strip of FeCr-alloy with the following approximate composition 0.7 wt-% C, 0.4 wt-% Si, 0.7 wt-% Mn and 13 wt-% Cr. This substrate material is commonly used in edge applications such as razor blades or knives.

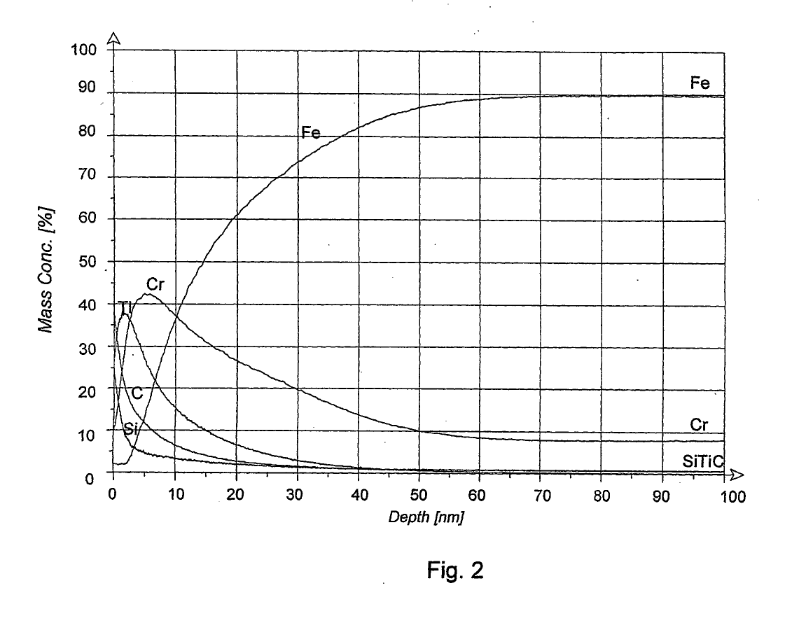

FIG. 2 shows a depth profile measured by GDOES. The relative mass concentration in the film at 5 nm have been measured to Ti˜26%; Si˜5%; C˜1%. This corresponds to a atomic Ti:Si relationship close to 3:1. The carbon content is relatively high (as discussed in Example 1, this not significant for such a thin film). Therefore, also this very thin MAX film shows an overall composition close to Ti:Si:C=3:1:2, as provided from the MAX target.

These two examples show that MAX coatings can be coated on to metallic substrates in accordance with the present invention.

1-8. (canceled)

9. A coated product consisting of:
a metal substrate; and
a coating, the coating having a composition of Mₙ₊₁A_{z}Xₙ,
wherein M is at least one transition metal selected from the group of Ti, Sc, V, Cr, Zr, Nb, Ta; A is at least one element selected from the group consisting of Si, Al, Ge and/or Sn; and X is at least one of the non-metals C and/or N, n is within the range of 0.8-3.2 and z is within the range of 0.8-1.2, and
wherein the metal substrate is at least 10 meters long.

10. The coated product according to claim 9 wherein the coating is substantially single phased.

11. The coated product according to claim 9 wherein the coating is substantially amorphous.

12. The coated product according to claim 9 wherein the coating is substantially crystalline.

13. The coated product according to claim 9 comprising a bonding layer located between the substrate and the coating.

14-17. (canceled)

18. The coated product according to claim 13, wherein a thickness of the bonding layer is not more than 50 nm.

19. The coated product according to claim 9, wherein the metal substrate is formed of a material selected from the group consisting of Fe, Cu, Al, Ti, Ni, Co and alloys based thereon.

20. The coated product according to claim 9, wherein the metal substrate is a stainless steel with a chromium content of at least 10 wt. %.

21. The coated product according to claim 9, wherein the metal substrate is at least 50 meters long.

22. The coated product according to claim 9, wherein the metal substrate has a thickness of 0.15 mm to 3 mm.

23. The coated product according to claim 22, wherein the metal substrate has a width of 1 mm to 1500 mm.

24. The coated product according to claim 9, wherein a thickness of the coating is 5 nm to 25 μm.

25. The coated product according to claim 24, wherein the thickness of the coating is 50 nm to 2 μm.

26. The coated product according to claim 9, wherein the coating is on both sides of the metal substrate.

27. A spring element comprising the coated product according to claim 9.

28. The spring element of claim 27, wherein the spring element is a metallic dome.

29. A fuel cell interconnect comprising the coated product according to claim 9, wherein the metal substrate is a ferritic stainless steel.

30. A medical device comprising the coated product according to claim 9.
